(19) United States
(12) Patent Application Publication
(10) Pub. No.: US 2026/0040796 A1
(43) Pub. Date: Feb. 5, 2026

(54) DISPLAY PANEL

(71) Applicant: Samsung Display Co., LTD., Yongin-si (KR)

(72) Inventors: Namjin Kim, Yongin-si (KR); Seongsik Ahn, Yongin-si (KR); Wonjang Ki, Yongin-si (KR); Yeonju Seo, Yongin-si (KR)

(21) Appl. No.: 19/281,123

(22) Filed: Jul. 25, 2025

(30) Foreign Application Priority Data
Aug. 1, 2024 (KR) 10-2024-0102708

(51) Int. Cl. H10K 59/80; H10K 59/122

(52) U.S. Cl. CPC H10K 59/873; H10K 59/122

(57) ABSTRACT

A display panel includes a substrate including an opening, a display area surrounding the opening, and an intermediate area disposed between the opening and the display area, a plurality of light-emitting diodes disposed on the display area of the substrate, and a dam disposed on the intermediate area of the substrate, wherein a first side of the dam includes a first tip protruding toward the display area, a second side of the dam includes a second tip protruding toward the opening, and the first tip and the second tip are disposed on different layers.

This application claims priority to Korean Patent Application No. 10-2024-0102708, filed on Aug. 1, 2024, and all the benefits accruing therefrom under 35 U.S.C. § 119, the content of which in its entirety is herein incorporated by reference.

### BACKGROUND

### 1. Field

The invention relates to a display panel, and more particularly to a display panel having an opening area inside of a display area.

### 2. Description of the Related Art

Recently, the usage of display apparatuses has diversified. Also, display apparatuses have become thinner and more lightweight, and thus, the use of display apparatuses has expanded.

As the area occupied by a display area in display apparatuses increases, various functions have been connected or linked to the display apparatuses. In order to further expand the area occupied of the display area and add various functions, studies have been conducted on display apparatuses in which various components may be arranged in the display area.

### SUMMARY

One or more embodiments include a display panel with improved display quality.

Additional aspects will be set forth in part in the description which follows and, in part, will be apparent from the description, or may be learned by practice of the presented invention.

According to one or more embodiments, a display panel includes a substrate including an opening, a display area surrounding the opening, and an intermediate area disposed between the opening and the display area, a plurality of light-emitting diodes disposed in the display area of the substrate, and a dam disposed in the intermediate area of the substrate, wherein a first side of the dam includes a first tip protruding toward the display area, a second side of the dam includes a second tip protruding toward the opening, and a first tip and a second tip are disposed on different layers.

According to one or more embodiments, when viewed from a direction perpendicular to the substrate, the dam may have a closed loop shape surrounding the opening.

According to one or more embodiments, the first tip and the second tip of the dam may be asymmetrical in a cross-section directed along a thickness direction of the substrate.

According to one or more embodiments, the display panel may further include at least one inorganic insulating layer disposed on the substrate, and a plurality of grooves disposed in the intermediate area of the substrate and in the at least one inorganic insulating layer.

According to one or more embodiments, the dam may include a first metal pattern layer disposed on the at least one inorganic insulating layer, an organic insulating layer disposed on the first metal pattern layer, and a second metal pattern layer disposed on the organic insulating layer.

According to one or more embodiments, the first tip may include the first metal pattern layer, and the second tip may include the second metal pattern layer.

According to one or more embodiments, the at least one inorganic insulating layer may be bisected by the first metal pattern layer.

According to one or more embodiments, each of the plurality of light-emitting diodes may be connected to a sub-pixel circuit disposed on the substrate, and the sub-pixel circuit may include a silicon transistor including a silicon-based semiconductor layer and an oxide transistor including an oxide-based semiconductor layer.

According to one or more embodiments, the first metal pattern layer may be disposed on a same layer as a node electrode connecting the silicon transistor to the oxide transistor, and the second metal pattern layer may be disposed on a same layer as a data line connected to the sub-pixel circuit.

According to one or more embodiments, a lower layer may be disposed under each of the plurality of grooves, and an upper surface of the lower layer may correspond to a bottom surface of each of the plurality of grooves.

According to one or more embodiments, the lower layer may include a same material as the oxide-based semiconductor layer.

According to one or more embodiments, the display panel may further include a first partition wall and a second partition wall disposed on the intermediate area of the substrate, wherein the first partition wall, the second partition wall, and the dam may be arranged along a direction from the display area toward the opening.

According to one or more embodiments, at least one groove among the plurality of grooves may be disposed between the second partition wall and the dam, and the first tip may protrude toward a groove disposed between the second partition wall and the dam.

According to one or more embodiments, the display panel may further include a first sub-partition wall and a second sub-partition wall disposed on the intermediate area of the substrate, wherein the first sub-partition wall and the second sub-partition wall may be disposed between the first partition wall and the second partition wall.

According to one or more embodiments, each of the plurality of light-emitting diodes may include an emission layer disposed between a first electrode and a second electrode, and a functional layer disposed between the first electrode and the second electrode, wherein the functional layer and the second electrode may be disconnected or separated by at least one of the first tip and the second tip.

According to one or more embodiments, the second side of the dam may further include a third tip protruding toward the opening, wherein the first tip and the third tip may be disposed on the same layer.

According to one or more embodiments, a display panel includes a substrate including an opening, a display area surrounding the opening, and an intermediate area disposed between the opening and the display area, at least one inorganic insulating layer disposed on the substrate, a plurality of light-emitting diodes disposed on the display area of the substrate, and a dam disposed on the intermediate area of the substrate, wherein the dam includes a first metal pattern layer disposed on the at least one inorganic insulating layer, an organic insulating layer disposed on the first metal pattern layer, and a second metal pattern layer disposed on the organic insulating layer, wherein the first metal pattern layer includes a first tip protruding toward the display area, and wherein the second metal pattern layer includes a second tip protruding toward the opening.

According to one or more embodiments, the first tip and the second tip of the dam may be asymmetrical in a cross-section along a thickness direction of the substrate.

According to one or more embodiments, the at least one inorganic insulating layer may be bisected by the first metal pattern layer.

According to one or more embodiments, the display panel may further include a plurality of grooves disposed in the intermediate area of the substrate and disposed on the at least one inorganic insulating layer.

According to one or more embodiments, the display panel may further include a first partition wall and a second partition wall disposed on the intermediate area of the substrate, wherein the first partition wall, the second partition wall, and the dam may be arranged along a direction from the display area toward the opening.

According to one or more embodiments, at least one groove among the plurality of grooves may be disposed between the second partition wall and the dam, and wherein the first tip may protrude toward a groove disposed between the second partition wall and the dam.

According to one or more embodiments, the display panel may further include a first sub-partition wall and a second sub-partition wall disposed on the intermediate area of the substrate, wherein the first sub-partition wall and the second sub-partition wall may be disposed between the first partition wall and the second partition wall.

According to one or more embodiments, each of the plurality of light-emitting diodes may include an emission layer disposed between a first electrode and a second electrode, and a functional layer disposed between the first electrode and the second electrode, wherein the functional layer and the second electrode may be disconnected or separated by at least one of the first tip and the second tip.

According to one or more embodiments, the first metal pattern layer may further include a third tip protruding toward the opening.

### BRIEF DESCRIPTION OF THE DRAWINGS

The above and other aspects, features, and advantages of the invention will be more apparent from the following description taken in conjunction with the accompanying drawings, in which:

FIG. 1 is a perspective view of an electronic apparatus, according to an embodiment.

FIG. 2 is a cross-sectional view of a display panel of the electronic apparatus taken along line I-I′ of FIG. 1, according to an embodiment.

FIG. 3 is a plan view of a display panel, according to an embodiment.

FIG. 4 is a schematic equivalent circuit diagram of a light-emitting diode and a sub-pixel circuit connected to the light-emitting diode, according to an embodiment.

FIG. 5 is a plan view of a portion of a display panel, according to an embodiment.

FIG. 6 is a cross-sectional view of the display panel taken along line VI-VI′ of FIG. 5, according to an embodiment.

FIG. 7 is a cross-sectional view of the display panel, taken along line VII-VII′ of FIG. 5, according to an embodiment.

FIG. 8 is a cross-sectional view of a display panel, according to another embodiment.

FIG. 9 is a block diagram of an electronic apparatus according to an embodiment.

FIG. 10 is a schematic diagrams of electronic apparatuses according to various embodiments.

### DETAILED DESCRIPTION

Reference will now be made in detail to embodiments, examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the invention allows for various changes and numerous embodiments, certain embodiments will be illustrated in the drawings and described in detail in the written description. Effects and features of the invention, and methods of achieving them will be clarified with reference to embodiments described below in detail with reference to the drawings. However, the invention is not limited to the following embodiments and may be embodied in various forms.

The invention will be described below in more detail with reference to the accompanying drawings. Those elements that are the same or are in correspondence with each other are rendered the same reference numeral regardless of the figure number, and redundant explanations are omitted.

It will be understood that although the terms “first,” “second,” etc. may be used herein to describe various elements, these elements should not be limited by these terms. These terms are only used to distinguish one element from another.

The singular forms “a,” “an,” and “the” as used herein are intended to include the plural forms as well unless the context clearly indicates otherwise.

It will be further understood that the terms “comprises” and/or “comprising” used herein specify the presence of stated features or elements, but do not preclude the presence or addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. For example, because sizes and thicknesses of elements in the drawings are arbitrarily illustrated for convenience of explanation, the invention is not limited thereto.

When a certain embodiment may be implemented differently, a specific process order may be performed differently from the described order. For example, two consecutively described processes may be performed substantially at the same time or performed in an order opposite to the described order.

It will be further understood that, when layers, regions, or components are referred to as being connected to each other, they may be directly connected to each other or indirectly connected to each other with intervening layers, regions, or components therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element disposed therebetween.

The x-axis, y-axis, and z-axis are not limited to three axes on the orthogonal coordinate system, but may be interpreted in a broad sense including the same. For example, the x-axis, y-axis, and z-axis may be orthogonal to each other, but they can also refer to different directions that are not orthogonal to each other.

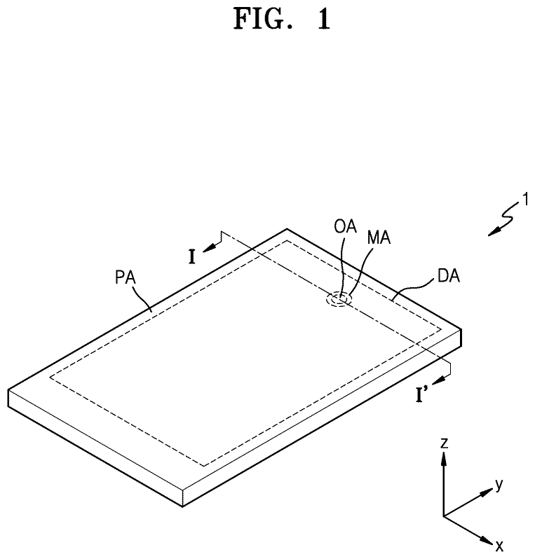

FIG. 1 is a perspective view of an electronic apparatus, according to an embodiment.

In an embodiment and referring to FIG. 1, an electronic apparatus 1 is configured to display a moving image or a still image and may be used as a display screen for various products, including not only portable electronic apparatuses, such as mobile phones, smartphones, tablet personal computers (PCs), mobile communication terminals, electronic notebooks, e-books, portable multimedia players (PMPs), navigations, and ultra mobile PCs (UMPCs), but also televisions (TVs), laptops, monitors, billboards, and internet of things (IoT) devices. The electronic apparatus 1, according to an embodiment, may also be used in wearable devices, such as smart watches, watch phones, glasses-type displays, or head mounted displays (HMDs). The electronic apparatus 1, according to an embodiment, may also be used as a dashboard of automobiles, center information displays (CIDs) on the center fascia or dashboards of automobiles, room mirror displays that replace side mirrors of automobiles, and displays arranged on the rear sides of front seats to serve as entertainment devices for backseat passengers of automobiles. In FIG. 1, for convenience of description, the electronic apparatus 1, according to an embodiment, is shown as being used as a smartphone.

In an embodiment, the electronic apparatus 1 may have a rectangular shape in a plan view. For example, as illustrated in FIG. 1, the electronic apparatus 1 may have a rectangular planar shape having a short side in an x direction and a long side in a y direction. An edge at which the short side in the x direction and the long side in the y direction meet each other may be formed to have a right angle or may be rounded to have a certain curvature. The planar shape of the electronic apparatus 1 is not limited to a rectangle, and may be another polygonal shape, an elliptical shape, or an irregular shape.

In an embodiment, the electronic apparatus 1 may include an opening area OA (or a first area) and a display area DA (or a second area) surrounding at least the opening area OA. The electronic apparatus 1 may include an intermediate area MA (or a third area) located between the opening area OA and the display area DA, and an outer area PA (or a fourth area) surrounding the display area DA, for example, outside of the display area DA. The intermediate area MA may have a closed loop shape that entirely surrounds the opening area OA in a plan view.

In an embodiment, the opening area OA may be positioned inside the display area DA. According to an embodiment and as illustrated in FIG. 1, the opening area OA may be in an upper center of the display area DA. In another embodiment, the opening area OA may be variously arranged. For example, the opening area OA may be in an upper left side of the display area DA or an upper right side of the display area DA. FIG. 1 illustrates one opening area OA, but in another embodiment, a plurality of opening areas OA may be provided.

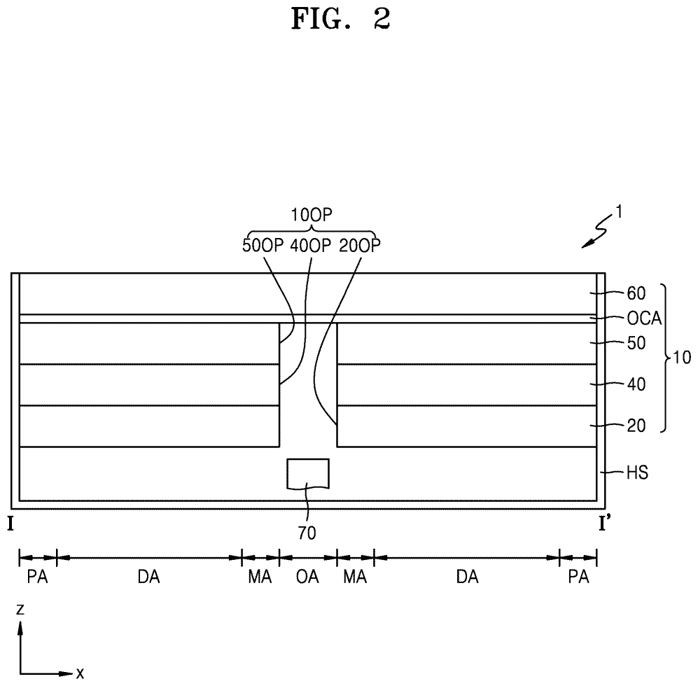

FIG. 2 is a cross-sectional view of a display panel 10 taken along line I-I′ of FIG. 1, according to an embodiment.

In an embodiment and referring to FIG. 2, the electronic apparatus 1 may include the display panel 10 and a component 70 in the opening area OA of the display panel 10. The display panel 10 and the component 70 may be accommodated in a housing HS.

In an embodiment, the display panel 10 may include an image generating layer 20, an input sensing layer 40, an optical functional layer 50, and a cover window 60.

In an embodiment, the image generating layer 20 may include display elements (or light-emitting elements) that emit light to display an image. The display elements may include a light-emitting diode, for example, an organic light-emitting diode including an organic emission layer. According to another embodiment, the light-emitting diode may include an inorganic light-emitting diode including an inorganic material. The inorganic light-emitting diode may include a PN junction diode including inorganic semiconductor-based materials. When a voltage is applied to the PN junction diode in a forward direction, holes and electrons may be injected and recombined to generate energy. The PN junction diode may convert the generated energy into light energy to emit light of a certain color. The inorganic light-emitting diode may have a width of several to several hundred micrometers or several to several hundred nanometers. According to some embodiments, the image generating layer 20 may include a quantum dot light-emitting diode. For example, an emission layer of the image generating layer 20 may include an organic material, an inorganic material, quantum dots, an organic material and quantum dots, or an inorganic material and quantum dots.

In an embodiment, the input sensing layer 40 may obtain coordinate information according to an external input, for example, a touch event. The input sensing layer 40 may include a sensing electrode (or a touch electrode) and trace lines electrically connected to the sensing electrode. The input sensing layer 40 may be on the image generating layer 20. The input sensing layer 40 may sense an external input by using a mutual cap method and/or a self cap method.

In an embodiment, the input sensing layer 40 may be formed directly on the image generating layer 20 or may be separately formed and then bonded through an adhesive layer such as an optical clear adhesive (OCA) layer. For example, the input sensing layer 40 may be continuously formed after the process of forming the image generating layer 20. In this case, the adhesive layer may not be disposed between the input sensing layer 40 and the image generating layer 20. FIG. 2 illustrates that the input sensing layer 40 is disposed between the image generating layer 20 and the optical functional layer 50, but in another embodiment, the input sensing layer 40 may be disposed on the optical functional layer 50.

In an embodiment, the optical functional layer 50 may include an anti-reflective layer, where the anti-reflective layer may reduce reflectance of light (external light) incident from the outside on the display panel 10 through the cover window 60. The anti-reflective layer may include a retarder and a polarizer. According to another embodiment, the anti-reflective layer may include a black matrix and color filters. The color filters may be arranged considering the color of light emitted from each light-emitting diode of the image generating layer 20.

In an embodiment and in order to improve the transmittance of the opening area OA, the display panel 10 may include an opening 10OP passing through some layers constituting the display panel 10. The opening 10OP may include first to third openings 20OP, 40OP, and 50OP, respectively, passing through the image generating layer 20, the input sensing layer 40, and the optical functional layer 50, respectively. The first opening 20OP of the image generating layer 20, the second opening 40OP of the input sensing layer 40, and the third opening 50OP of the optical functional layer 50 may overlap each other to form the opening 10OP of the display panel 10.

In an embodiment, the cover window 60 may be disposed on the optical functional layer 50 and may be bonded to the optical functional layer 50 through an adhesive layer such as an OCA layer. The cover window 60 may cover the first opening 20OP of the image generating layer 20, the second opening 40OP of the input sensing layer 40, and the third opening 50OP of the optical functional layer 50.

In an embodiment, the cover window 60 may include a glass material or a plastic material. The glass material may include ultra-thin glass. The plastic material may include polyethersulfone, polyacrylate, polyetherimide, polyethylene naphthalate, polyethylene terephthalate, polyphenylene sulfide, polyarylate, polyimide, polycarbonate, or cellulose acetate propionate.

In an embodiment, the opening area OA may be a component area (e.g., a sensor area, a camera area, a speaker area, etc.) in which the component 70 for adding various functions to the electronic apparatus 1 is positioned.

In an embodiment, the component 70 may include an electronic element. For example, the component 70 may include an electronic element using light or sound. For example, the electronic element may include a sensor (e.g., an infrared sensor) using light, a camera configured to receive light to capture an image, a sensor configured to measure a distance or recognizes a fingerprint by outputting and sensing light or sound, a small lamp configured to output light, a speaker configured to output sound, and the like. The electronic element may use light in various wavelength bands such as visible light, infrared light, and ultraviolet light. The opening area OA may correspond to an area through which light or/and sound that is output from the component 70 to the outside or directed from the outside to the electronic element may be transmitted.

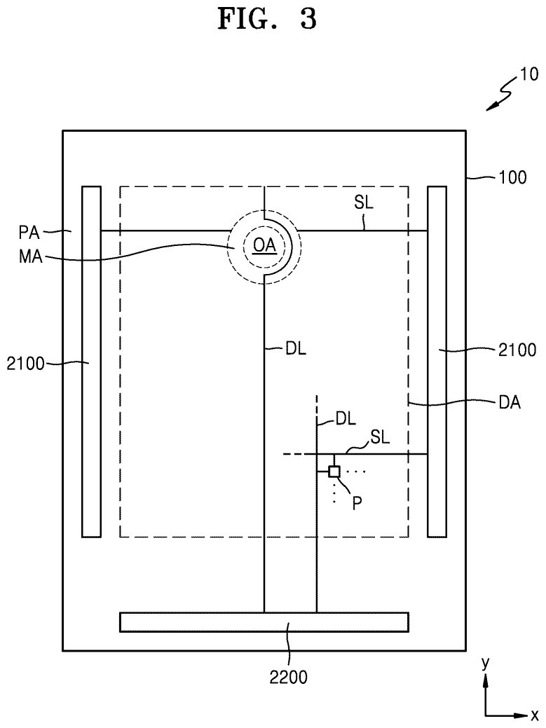

FIG. 3 is a plan view of the display panel 10, according to an embodiment.

In an embodiment and referring to FIG. 3, the display panel 10 may include the opening area OA, the display area DA, the intermediate area MA, and the outer area PA.

In an embodiment, the display panel 10 may include a plurality of sub-pixels P in the display area DA and may display an image using light emitted from each of the plurality of sub-pixels P. Each of the plurality of sub-pixels P may emit red light, green light, or blue light by using a light-emitting diode. The light-emitting diode of each of the plurality of sub-pixels P may be electrically connected to a scan line SL and a data line DL.

In an embodiment, a scan driver 2100 configured to provide a scan signal to each of the plurality of sub-pixels P, a data driver 2200 configured to provide a data signal to each of the plurality of sub-pixels P, and a first main power line (not illustrated) and a second main power line (not illustrated) configured to provide a first power supply voltage and a second power supply voltage may be arranged in the outer area PA. Scan drivers 2100 may be arranged on either side of the display area DA. In this case, the plurality of sub-pixels P disposed on the left side of the opening area OA may be connected to the scan driver 2100 on the left side, and the plurality of sub-pixels P disposed on the right side of the opening area OA may be connected to the scan driver 2100 on the right side.

In an embodiment, the intermediate area MA may surround the opening area OA. The intermediate area MA is an area in which no display elements such as light-emitting diodes are arranged. Signal lines configured to provide signals to the plurality of sub-pixels P around the opening area OA may pass through the intermediate area MA. For example, data lines DL and/or scan lines SL may cross the display area DA, but some data lines DL and/or some scan lines SL may bypass in the intermediate area MA along the edge of the opening 10OP (see FIG. 2) of the display panel 10 provided in the opening area OA. According to an embodiment, FIG. 3 illustrates that the data lines DL cross the display area DA in the y direction, but some data lines DL bypass and partially surround the opening area OA in the intermediate area MA. The scan lines SL may cross the display area DA in the x direction, but may be spaced apart from each other with the opening area OA therebetween.

FIG. 3 illustrates an embodiment where the data driver 2200 is disposed adjacent to one side of a substrate 100, but in another embodiment, the data driver 2200 may be on a printed circuit board electrically connected to a pad on one side of the display panel 10. The printed circuit board may be flexible, and a portion of the printed circuit board may be bent so as to be positioned under a rear surface of the substrate 100.

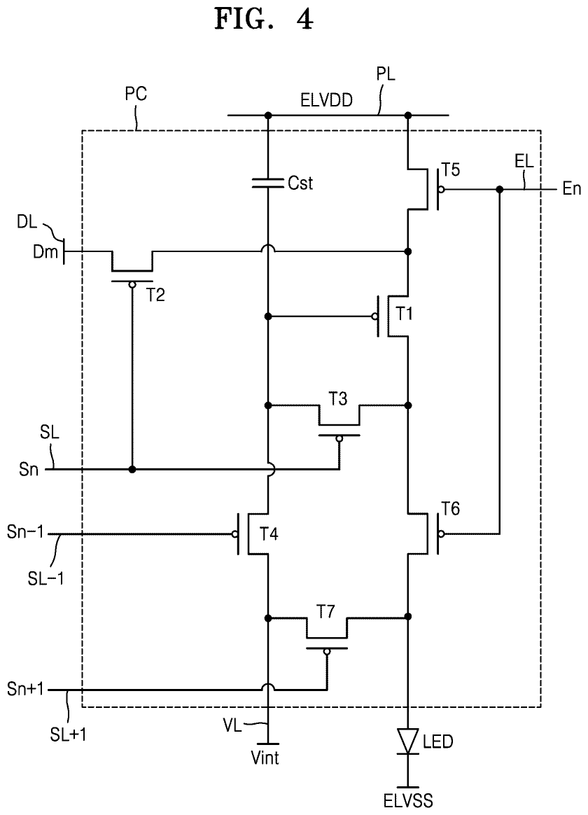

FIG. 4 is a schematic equivalent circuit diagram of a light-emitting diode LED and a sub-pixel circuit PC connected to the light-emitting diode LED, according to an embodiment.

In an embodiment and referring to FIG. 4, the sub-pixel P described with reference to FIG. 3 may emit light from the light-emitting diode LED, and the light-emitting diode LED may be electrically connected to a sub-pixel circuit PC.

In an embodiment, the sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

In an embodiment, the second thin-film transistor T2 acts as a switching thin-film transistor and may be connected to a scan line SL and a data line DL and may be configured to transmit a data voltage (or a data signal Dm) input from the data line DL to the first thin-film transistor T1, based on a switching voltage (or a switching signal Sn) input from the scan line SL. The storage capacitor Cst may be connected to the first thin-film transistor T1 and a driving voltage line PL and may be configured to store a voltage corresponding to a difference between a voltage received from the first thin-film transistor T1 and a first power supply voltage ELVDD supplied to the driving voltage line PL.

In an embodiment, the first thin-film transistor T1 acts as a driving thin-film transistor. The first thin-film transistor T1 may be connected to the driving voltage line PL and the storage capacitor Cst and may be configured to control a driving current flowing from the driving voltage line PL to the light-emitting diode LED in response to a voltage value stored in the storage capacitor Cst. The light-emitting diode LED may emit light having a certain luminance according to the driving current. A second electrode (e.g., a cathode) of the light-emitting diode LED may be configured to receive a second power supply voltage ELVSS.

In an embodiment, the third thin-film transistor T3 acts as a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1 and to a first electrode of the light-emitting diode LED via the sixth thin-film transistor T6. The drain electrode (or the source electrode) of the third thin-film transistor T3 may be connected to any one electrode of the storage capacitor Cst, a source electrode (or a drain electrode) of the fourth thin-film transistor T4, and a gate electrode of the first thin-film transistor T1. The third thin-film transistor T3 may be turned on in response to the scan signal Sn received through the scan line SL. Accordingly, the gate electrode and the drain electrode of the first thin-film transistor T1 are connected to each other, and thus, the first thin-film transistor T1 may function as a diode-connected transistor.

In an embodiment, the fourth thin-film transistor T4 acts as an initialization thin-film transistor, and a gate electrode of the fourth thin-film transistor T4 may be connected to a previous scan line SL−1. The drain electrode (or the source electrode) of the fourth thin-film transistor T4 may be connected to an initialization voltage line VL. The source electrode (or the drain electrode) of the fourth thin-film transistor T4 may be connected to any one electrode of the storage capacitor Cst, the source electrode (or the drain electrode) of the third thin-film transistor T3, and the gate electrode of the first thin-film transistor T1. The fourth thin-film transistor T4 may be turned on in response to a previous scan signal Sn−1 received through the previous scan line SL−1 and perform an initialization operation of initializing the voltage of the gate electrode of the first thin-film transistor T1 by transmitting an initialization voltage Vint to the gate electrode of the first thin-film transistor T1.

In an embodiment, the fifth thin-film transistor T5 acts as an operation control thin-film transistor, and a gate electrode of the fifth thin-film transistor T5 may be connected to an emission control line EL. A source electrode (or a drain electrode) of the fifth thin-film transistor T5 may be connected to the driving voltage line PL. The drain electrode (or the source electrode) of the fifth thin-film transistor T5 may be connected to the source electrode (or the drain electrode) of the first thin-film transistor T1 and a drain electrode (or a source electrode) of the second thin-film transistor T2.

In an embodiment, the sixth thin-film transistor T6 acts as an emission control thin-film transistor, and a gate electrode of the sixth thin-film transistor T6 may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on in response to an emission control signal En received through the emission control line EL, so that the first power supply voltage ELVDD is transmitted to the light-emitting diode LED and the driving current flows through the light-emitting diode LED.

In an embodiment, the seventh thin-film transistor T7 may be an initialization thin-film transistor configured to initialize the first electrode of the light-emitting diode LED. A gate electrode of the seventh thin-film transistor T7 may be connected to a next scan line SL+1. A source electrode (or a drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on in response to a next scan signal Sn+1 received through the next scan line SL+1 and initialize the first electrode of the light-emitting diode LED.

FIG. 4 illustrates an embodiment in which the fourth thin-film transistor T4 and the seventh thin-film transistor T7 are connected to the previous scan line SL−1 and the next scan line SL+1, respectively, but in another embodiment, both the fourth thin-film transistor T4 and the seventh thin-film transistor T7 may be connected to the previous scan line SLn−1 and may be driven in response to the previous scan signal Sn−1.

In an embodiment, the other electrode of the storage capacitor Cst may be connected to the driving voltage line PL. Any one electrode of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4.

In an embodiment, the second electrode (e.g., the cathode) of the light-emitting diode LED may be configured to receive the second power supply voltage ELVSS. The light-emitting diode LED receives the driving current from the first thin-film transistor T1 and emits light.

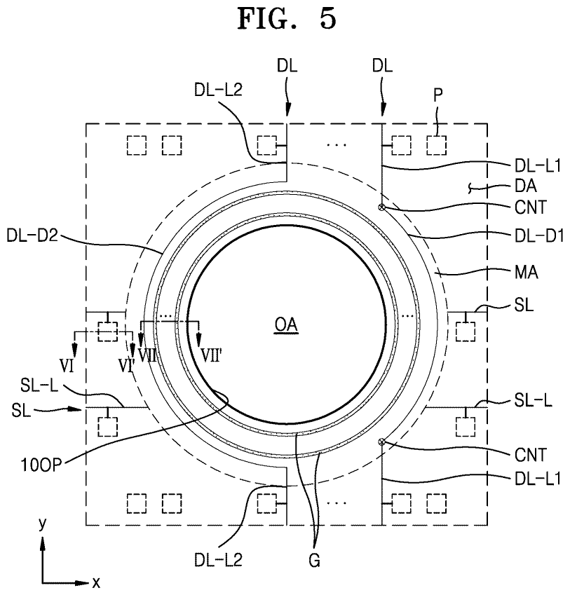

FIG. 5 is a plan view of a portion of the display panel 10, according to an embodiment.

In an embodiment and referring to FIG. 5, the plurality of sub-pixels P are disposed in the display area DA. The intermediate area MA may be disposed between the opening area OA and the display area DA. The plurality of sub-pixels P disposed adjacent to the opening area OA may be spaced apart from each other with the opening area OA disposed therebetween in a plan view. In the plan view of FIG. 5, the plurality of sub-pixels P may be disposed to be vertically spaced apart from each other with the opening area OA disposed therebetween, or may be disposed to be horizontally spaced apart from each other with the opening area OA disposed therebetween. As described above with reference to FIGS. 3 and 4, because the plurality of sub-pixels P use red light, green light, and blue light emitted from light-emitting diodes, the positions of the plurality of sub-pixels P illustrated in FIG. 4 correspond to the positions of the light-emitting diodes, respectively. Therefore, the plurality of sub-pixels P being spaced apart from each other with the opening area OA disposed therebetween in a plan view may mean that the light-emitting diodes are spaced apart from each other with the opening area OA disposed therebetween in a plan view. For example, in a plan view, the light-emitting diodes may be disposed to be vertically spaced apart from each other with the opening area OA disposed therebetween, or may be disposed to be horizontally spaced apart from each other with the opening area OA disposed therebetween.

In an embodiment, among signal lines configured to supply signals to the sub-pixel circuit connected to the light-emitting diode of each of the plurality of sub-pixels P, signal lines disposed adjacent to the opening area OA may bypass the opening area OA and/or the opening 10OP. Some data lines DL passing through the display area DA may extend in the +y direction such that data signals are provided to the sub-pixels P above and below the opening area OA, and may bypass along the edge of the opening area OA and/or the opening 10OP in the intermediate area MA.

In an embodiment, a bypass portion DL-D1 of at least one data line DL may be disposed on a layer different from an extension portion DL-L1 crossing the display area DA, and a bypass portion DL-D1 of the data line DL and the extension portion DL-L1 may be connected to each other through a contact hole CNT. A bypass portion DL-D2 of at least one of the data lines DL may be disposed on the same layer as an extension portion DL-L2, and the bypass portion DL-D2 may be integral with the extension portion DL-L2.

In an embodiment, the scan line SL may be separated or disconnected with the opening area OA disposed therebetween. As described above with reference to FIG. 3, the scan line SL disposed on the left side of the opening area OA may be configured to receive a signal from the scan driver 2100 disposed on the left side of the display area DA, and the scan line SL disposed on the right side of the opening area OA may be configured to receive a signal from the scan driver 2100 disposed on the right side of the display area DA.

In an embodiment, grooves G may be disposed between the opening area OA and the area of the intermediate area MA that the data lines DL bypass. The grooves G may each have a closed loop shape surrounding the opening area OA in a plan view, and the grooves G may be spaced apart from each other.

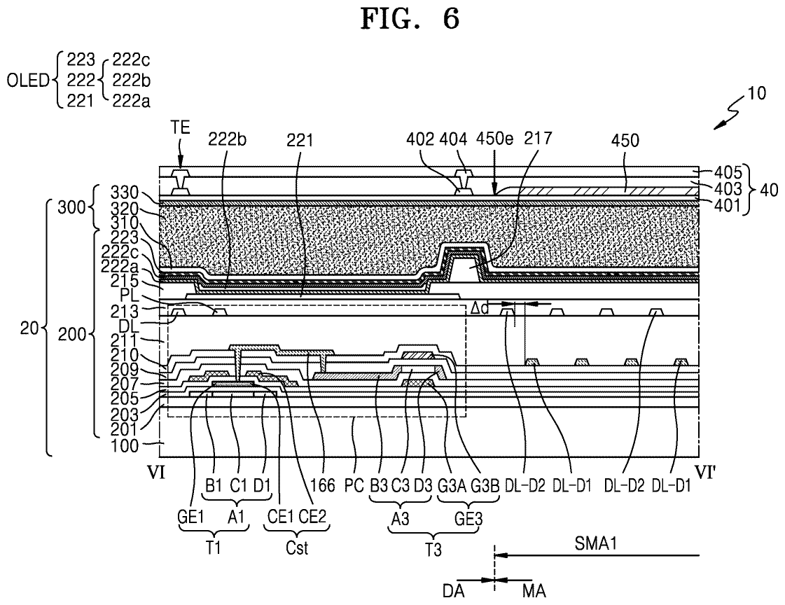

FIG. 6 is a cross-sectional view of the display panel 10 taken along line VI-VI′ of FIG. 5, according to an embodiment.

In an embodiment and referring to the display area DA of FIG. 6, the substrate 100 may include a glass material or a polymer resin. According to an embodiment, the substrate 100 may have a structure in which a base layer including a polymer resin and a barrier layer including an inorganic insulating material such as silicon oxide or silicon nitride are alternately stacked. The polymer resin may include a polymer resin such as polyethersulfone, polyarylate, polyether imide, polyethylene naphthalate, polyethylene terephthalate, polyphenylene sulfide, polyimide, polycarbonate, cellulose triacetate, and cellulose acetate propionate.

In an embodiment, the sub-pixel circuit PC may be on the substrate 100, and the light-emitting diode such as the organic light-emitting diode OLED may be on the sub-pixel circuit PC.

In an embodiment, before the sub-pixel circuit PC is formed, a buffer layer 201 may be formed on the substrate 100 so as to prevent infiltration of impurities into the sub-pixel circuit PC. The buffer layer 201 may include an inorganic insulating material such as silicon nitride, silicon oxynitride, and silicon oxide, and may include a single-layer structure or a multilayer structure including the afore-described inorganic insulating material.

In an embodiment, although not illustrated in FIG. 6, a lower metal layer (not illustrated) may be additionally disposed between the substrate 100 and the buffer layer 201. The lower metal layer may be disposed to overlap a semiconductor layer and has a constant voltage level to prevent negative (−) charges from gathering under the semiconductor layer of the transistor, and to prevent or minimize the occurrence of an afterimage caused by the negative (−) charges. The lower metal layer may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

In an embodiment, the sub-pixel circuit PC may include a plurality of transistors and a storage capacitor, as described above with reference to FIG. 4. In this regard, FIG. 6 illustrates a first thin-film transistor T1, a third thin-film transistor T3, and a storage capacitor Cst.

In an embodiment, the first thin-film transistor T1 may include a semiconductor layer (hereinafter referred to as a first semiconductor layer A1) disposed on the buffer layer 201 and a gate electrode (hereinafter referred to as a first gate electrode GE1) overlapping a channel region C1 of the first semiconductor layer A1. The first semiconductor layer A1 may include a silicon-based semiconductor material, for example, polysilicon. The first semiconductor layer A1 may include the channel region C1, and a first region B1 and a second region D1 disposed on both sides of the channel region C1. The first region B1 and the second region D1 are regions including a higher concentration of impurities than the channel region C1. One of the first region B1 and the second region D1 may correspond to a source region and the other thereof may correspond to a drain region.

In an embodiment, a first gate insulating layer 203 may be disposed between the first semiconductor layer A1 and the first gate electrode GE1. The first gate insulating layer 203 may include an inorganic insulating material such as silicon oxide, silicon nitride, and silicon oxynitride, and may include a single-layer structure or a multilayer structure including the above-described inorganic insulating material.

In an embodiment, the first gate electrode GE1 may include a conductive material including molybdenum (Mo), aluminum (Al), copper (Cu), titanium (Ti), and the like, and may include a single layer or multiple layers including the above-described material.

In an embodiment, the storage capacitor Cst may include a lower electrode CE1 and an upper electrode CE2 overlapping each other. According to an embodiment, the lower electrode CE1 of the storage capacitor Cst may include the first gate electrode GE1. In other words, the first gate electrode GE1 may include the lower electrode CE1 of the storage capacitor Cst. For example, the first gate electrode GE1 may be integral with the lower electrode CE1 of the storage capacitor Cst.

In an embodiment, a first interlayer insulating layer 205 may be disposed between the lower electrode CE1 and the upper electrode CE2 of the storage capacitor Cst. The first interlayer insulating layer 205 may include an inorganic insulating material such as silicon oxide, silicon nitride, and silicon oxynitride, and may include a single-layer structure or a multilayer structure including the above-described inorganic insulating material.

In an embodiment, the upper electrode CE2 of the storage capacitor Cst may include a low-resistance conductive material such as molybdenum (Mo), aluminum (Al), copper (Cu), and/or titanium (Ti), and may include a single-layer structure or a multilayer structure including the above-described material.

In an embodiment, a second interlayer insulating layer 207 may be disposed on the storage capacitor Cst and may include an inorganic insulating material such as silicon oxide, silicon nitride, and silicon oxynitride, and may further include a single-layer structure or a multilayer structure including the above-described inorganic insulating material.

In an embodiment, a semiconductor layer (hereinafter referred to as a third semiconductor layer A3) of the third thin-film transistor T3 may be disposed on the second interlayer insulating layer 207. The third semiconductor layer A3 may include an oxide-based semiconductor material. For example, the third semiconductor layer A3 may include a Zn oxide-based material, for example, Zn oxide, In—Zn oxide, Ga—In—Zn oxide, or the like. According to some embodiments, the third semiconductor layer A3 may include In—Ga—Zn—O (IGZO), In—Sn—Zn—O (ITZO), or In—Ga—Sn—Zn—O (IGTZO) semiconductor, in which a metal such as indium (In), gallium (Ga), and tin (Sn) is included in ZnO.

In an embodiment, the third semiconductor layer A3 may include a channel region C3, and a first region B3 and a second region D3 disposed on both sides of the channel region C3. One of the first region B3 and the second region D3 may correspond to a source region and the other one may correspond to a drain region.

In an embodiment, the third thin-film transistor T3 may include a gate electrode (hereinafter referred to as a third gate electrode GE3) overlapping the channel region C3 of the third semiconductor layer A3. The third gate electrode GE3 may have a double gate structure including a lower gate electrode G3A below the third semiconductor layer A3 and an upper gate electrode G3B above the channel region C3.

In an embodiment, the lower gate electrode G3A may be disposed on a same layer (e.g., the first interlayer insulating layer 205) as the upper electrode CE2 of the storage capacitor Cst. The lower gate electrode G3A may include a same material as that of the upper electrode CE2 of the storage capacitor Cst.

In an embodiment, the upper gate electrode G3B may be disposed above the third semiconductor layer A3 with the second gate insulating layer 209 disposed therebetween. The second gate insulating layer 209 may include an inorganic insulating material such as silicon oxide, silicon nitride, and silicon oxynitride, and may include a single-layer structure or a multilayer structure including the above-described inorganic insulating material.

In an embodiment, the third interlayer insulating layer 210 may be on the upper gate electrode G3B. The third interlayer insulating layer 210 may include an inorganic insulating material such as silicon oxynitride. The third interlayer insulating layer 210 may include a single-layer structure or a multilayer structure including the above-described inorganic insulating material.

Although FIG. 6 illustrates the first thin-film transistor T1 and the third thin-film transistor T3 among the thin-film transistors as described above with reference to FIG. 4 and illustrates that the first semiconductor layer A1 and the third semiconductor layer A3 are disposed on different layers from each other, the invention is not limited thereto.

In an embodiment, each of the thin-film transistors T2, T5, T6, and T7, which have been described above with reference to FIG. 4, may have a same structure as that of the first thin-film transistor T1 described above with reference to FIG. 6. For example, each of the thin-film transistors T2, T5, T6, and T7 (see FIG. 4) may include a semiconductor layer disposed on a same layer as the first semiconductor layer A1 of the first thin-film transistor T1 and a gate electrode on a same layer as the first gate electrode GE1 of the first thin-film transistor T1. The semiconductor layer of each of the thin-film transistors T2, T5, T6, and T7 (see FIG. 4) may be integrally connected to the first semiconductor layer A1.

In an embodiment, the fourth thin-film transistor T4 described above with reference to FIG. 4 may have a same structure as that of the third thin-film transistor T3 described above with reference to FIG. 6. For example, the fourth thin-film transistor T4 may include a semiconductor layer disposed on a same layer as the third semiconductor layer A3 of the third thin-film transistor T3 and a gate electrode disposed on the same layer as the third gate electrode GE3 of the third thin-film transistor T3. The semiconductor layer of the fourth thin-film transistor T4 may be integrally connected to the third semiconductor layer A3 of the third thin-film transistor T3.

In an embodiment, the first thin-film transistor T1 and the third thin-film transistor T3 may be electrically connected to each other through a node connection line 166 (or a node electrode). The node connection line 166 may be disposed on the third interlayer insulating layer 210. One side of the node connection line 166 may be connected to the first gate electrode GE1 of the first thin-film transistor T1, and the other side of the node connection line 166 may be connected to the third semiconductor layer A3 of the third thin-film transistor T3.

In an embodiment, the node connection line 166 may include aluminum (Al), copper (Cu), and/or titanium (Ti), and may include a single layer or multiple layers including the above-described material. For example, the node connection line 166 may have a three-layer structure of Ti/Al/Ti.

In an embodiment, a first organic insulating layer 211 may be disposed on the node connection line 166 and may include an organic insulating material. The organic insulating material may include acryl, benzocyclobutene (BCB), polyimide, or hexamethyldisiloxane (HMDSO).

In an embodiment, a data line DL and a driving voltage line PL may be disposed on the first organic insulating layer 211, and may be covered with a second organic insulating layer 213. The data line DL and the driving voltage line PL may include aluminum (Al), copper (Cu), and/or titanium (Ti), and may include a single layer or multiple layers including the above-described material. For example, the data line DL and the driving voltage line PL may have a three-layer structure of Ti/Al/Ti.

In an embodiment, the second organic insulating layer 213 may include an organic insulating material such as acryl, BCB, polyimide, and/or HMDSO. Although FIG. 6 illustrates that the data line DL and the driving voltage line PL are disposed on the first organic insulating layer 211, the invention is not limited thereto. According to another embodiment, one of the data line DL and the driving voltage line PL may be disposed on the same layer as the node connection line 166.

In an embodiment, a light-emitting diode such as an organic light-emitting diode OLED may be disposed on the second organic insulating layer 213.

In an embodiment, a first electrode 221 of the organic light-emitting diode OLED may include a reflective layer including silver (Ag), magnesium (Mg), aluminum (Al), platinum (Pt), palladium (Pd), gold (Au), nickel (Ni), neodymium (Nd), Iridium (Ir), chromium (Cr), or any compound thereof. According to another embodiment, the first electrode 221 may further include a conductive oxide layer above and/or below the above-described reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to an embodiment, the first electrode 221 may have a three-layer structure of ITO/Ag/ITO.

In an embodiment, a bank layer 215 may be disposed on the first electrode 221 and may include an opening overlapping the first electrode 221, and may cover the edge of the first electrode 221. The bank layer 215 may include an organic insulating material.

In an embodiment, an intermediate layer 222 may include an emission layer 222b. The intermediate layer 222 may include a first functional layer 222a disposed below the emission layer 222b and/or a second functional layer 222c disposed on the emission layer 222b. The emission layer 222b may include a high molecular weight organic material or a low molecular weight organic material that emits light of a certain color. The second functional layer 222c may include an electron transport layer (ETL) and/or an electron injection layer (EIL). The first functional layer 222a and the second functional layer 222c may each include an organic material.

In an embodiment, the second electrode 223 may include a conductive material having a low work function. For example, the second electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. In another embodiment, the second electrode 223 may further include a layer such as ITO, IZO, ZnO, or In₂O₃ on the (semi) transparent layer including the above-described material.

In an embodiment, the emission layer 222b may be disposed on the display area DA and overlap the first electrode 221 through the opening of the bank layer 215. The first functional layer 222a, the second functional layer 222c, and the second electrode 223 may extend to be positioned in the intermediate area MA as well as the display area DA.

In an embodiment, spacers 217 may be disposed on the bank layer 215. The spacers 217 may be formed together with the bank layer 215 in a same process or may be individually formed in separate processes. According to an embodiment, each of the spacers 217 may include an organic insulating material such as polyimide.

In an embodiment, the organic light-emitting diode OLED may be covered with an encapsulation layer 300, where the encapsulation layer 300 may include at least one organic encapsulation layer and at least one inorganic encapsulation layer. According to an embodiment, FIG. 6 illustrates that the encapsulation layer 300 includes first and second inorganic encapsulation layers 310 and 330, respectively, with an organic encapsulation layer 320 disposed therebetween.

In an embodiment, the first inorganic encapsulation layer 310 and the second inorganic encapsulation layer 330 may each include one or more inorganic materials selected from aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may be a single layer or multiple layers including the above-described material. The organic encapsulation layer 320 may include a polymer-based material. The polymer-based material may include an acrylic resin, an epoxy-based resin, polyimide, polyethylene, and the like. According to an embodiment, the organic encapsulation layer 320 may include acrylate.

In an embodiment, the first inorganic encapsulation layer 310 and the second inorganic encapsulation layer 330 may have different thicknesses from each other. A thickness of the first inorganic encapsulation layer 310 may be greater than a thickness of the second inorganic encapsulation layer 330. In another embodiment, the thickness of the second inorganic encapsulation layer 330 may be greater than the thickness of the first inorganic encapsulation layer 310, or the thickness of the first inorganic encapsulation layer 310 may be equal to the thickness of the second inorganic encapsulation layer 330.

In an embodiment, the display panel 10 may include the substrate 100, an image generating layer 20 disposed on the substrate 100 and including a circuit-diode layer 200 and the encapsulation layer 300, and an input sensing layer 40 disposed on the image generating layer 20. The circuit-diode layer 200 may include pixel circuits and light-emitting diodes.

In an embodiment, the input sensing layer 40 may include a first touch insulating layer 401 disposed on the second inorganic encapsulation layer 330, a first conductive layer 402 disposed on the first touch insulating layer 401, a second touch insulating layer 403 disposed on the first conductive layer 402, a second conductive layer 404 disposed on the second touch insulating layer 403, and a third touch insulating layer 405 disposed on the second conductive layer 404.

In an embodiment, each of the first touch insulating layer 401, the second touch insulating layer 403, and the third touch insulating layer 405 may include an inorganic insulating material and/or an organic insulating material. According to an embodiment, each of the first touch insulating layer 401 and the second touch insulating layer 403 may include an inorganic insulating material such as silicon oxide, silicon nitride, and/or silicon oxynitride, and the third touch insulating layer 405 may include an organic insulating material.

In an embodiment, t touch electrode TE of the input sensing layer 40 may include a structure in which the first conductive layer 402 and the second conductive layer 404 are connected to each other. In another embodiment, the touch electrode TE may be disposed on one of the first conductive layer 402 and the second conductive layer 404, and may include a metal line provided in the corresponding conductive layer. Each of the first conductive layer 402 and the second conductive layer 404 may include aluminum (Al), copper (Cu), and/or titanium (Ti), and may include a single layer or multiple layers including the above-described material. For example, each of the first conductive layer 402 and the second conductive layer 404 may have a three-layer structure of Ti/Al/Ti.

In an embodiment and referring to the intermediate area MA of FIG. 6, the intermediate area MA may include a first sub-intermediate area SMA1 through which the bypass portions DL-D1 and DL-D2 of the data lines DL described above with reference to FIG. 5 pass.

In an embodiment, the bypass portions DL-D1 and DL-D2 of the data lines DL may be disposed on different layers from each other. One of the bypass portions DL-D1 and DL-D2 of the adjacent data lines DL may be disposed on the third interlayer insulating layer 210, and the other thereof may be disposed on the first organic insulating layer 211.

In an embodiment, when the bypass portions DL-D1 and DL-D2 of the data lines DL are alternately arranged with an insulating layer (e.g., first organic insulating layer 211) therebetween, a pitch Δd disposed between the bypass portions DL-D1 and DL-D2 of the data lines DL may be reduced. Therefore, the area in the intermediate area MA may be efficiently utilized.

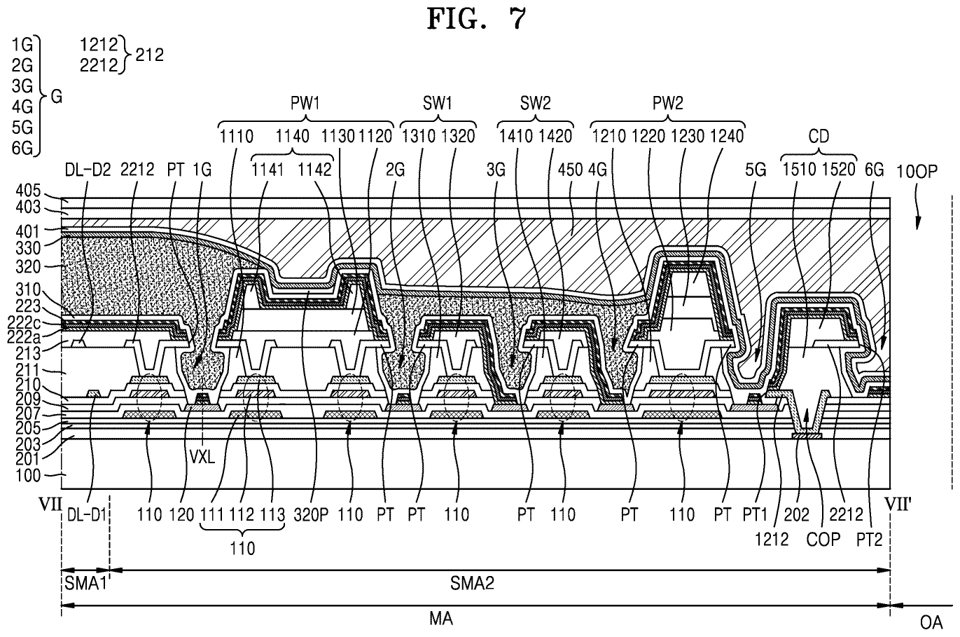

FIG. 7 is a cross-sectional view of the display panel 10 taken along line VII-VII′ of FIG. 5, according to an embodiment.

In an embodiment and referring to FIGS. 6 and 7, the intermediate area MA may include a first sub-intermediate area SMA1 disposed adjacent to the display area DA (see FIG. 6) and a second sub-intermediate area SM2 disposed adjacent to the opening area OA. The bypass portions DL-D1 and DL-D2 of the data lines DL described above with reference to FIG. 6 may be disposed in the first sub-intermediate area SMA1, and the bypass portions DL-D1 and DL-D2 of the data lines DL illustrated in the first sub-intermediate area SMA1 of FIG. 7 may correspond to some data lines described above with reference to FIG. 6.

In an embodiment, the bypass portions DL-D1 and DL-D2 of the data lines DL may be disposed in the first sub-intermediate area SMA1 of FIG. 7, the grooves G and partition walls may be in the second sub-intermediate area SMA2, and the encapsulation layer 300 may extend to the intermediate area MA and cover the grooves G and the partition walls.

In an embodiment and referring to the second sub-intermediate area SMA2 of FIG. 7, the grooves G may be spaced apart from each other. In this regard, FIG. 7 illustrates that first to sixth grooves 1G, 2G, 3G, 4G, 5G, and 6G, respectively, are arranged in a direction from the first sub-intermediate area SMA1 to the opening area OA. The grooves 1G, 2G, 3G, 4G, 5G, and 6G may have a closed loop shape surrounding the opening area OA in a plan view as described above with reference to FIG. 5.

In an embodiment, the groove G may pass through at least one insulating layer on the buffer layer 201. The at least one insulating layer in which the groove G is defined may include the first organic insulating layer 211, and may further include an insulating layer(s) disposed below the first organic insulating layer 211. In this regard, FIG. 7 illustrates that the grooves 1G, 2G, 3G, 4G and 5G pass through the second gate insulating layer 209, the third interlayer insulating layer 210, and the first organic insulating layer 211. The grooves G, for example, the grooves 1G, 2G, 3G, 4G and 5G may be defined by removing portions of the second gate insulating layer 209, the third interlayer insulating layer 210, and the first organic insulating layer 211 by an etching process.

In an embodiment, t lower layer 120 may be positioned directly below the groove G and may function as an etch stopper during an etching process for forming the groove G. Therefore, the bottom surface of the groove G may be the upper surface of the lower layer 120. In this regard, FIG. 7 illustrates that the lower layer 120 is positioned below each of the grooves 1G, 2G, 3G, 4G and 5G, and the bottom surface of each of the grooves 1G, 2G, 3G, 4G and 5G is coplanar with the upper surface of the lower layer 120.

In an embodiment, the lower layer 120 may be positioned on the second interlayer insulating layer 207 and may be formed together with the third semiconductor layer A3 (see FIG. 6) described above with reference to FIG. 6 in the same process. The lower layer 120 may include the same material as that of the third semiconductor layer A3, for example, an oxide-based semiconductor material. Like the groove G, the lower layer 120 may have a closed loop shape surrounding the opening area OA in a plan view.

In an embodiment, when the groove G is not formed on the substrate 100 and is formed on at least one inorganic insulating layer as in the embodiment, moisture that may be introduced through the substrate 100 may be blocked by the at least one inorganic insulating layer. In this regard, FIG. 7 illustrates a structure in which a groove G is formed on the buffer layer 201, the first gate insulating layer 203, the first interlayer insulating layer 205, and the second interlayer insulating layer 207, such that the buffer layer 201, the first gate insulating layer 203, the first interlayer insulating layer 205, and the second interlayer insulating layer 207 effectively block moisture that may be introduced through the substrate 100.

In an embodiment, since the grooves G are formed by penetrating at least one insulating layer, partition walls in addition to the grooves G may be located in the intermediate area MA. In this regard, FIG. 7 illustrates a first partition wall PW1, a second partition wall PW2, a first sub-partition wall SW1, a second sub-partition wall SW2, and a dam CD. The grooves G including grooves 1G to 6G may be spaced apart from each other in the second sub-intermediate area SMA2. The first partition wall PW1, the second partition wall PW2, the first sub-partition wall SW1, the second sub-partition wall SW2, and the dam CD may have a closed loop shape in a plan view, similar to the grooves G.

In an embodiment, the first partition wall PW1, the first sub-partition wall SW1, the second sub-partition wall SW2, the second partition wall PW2, and the dam CD may be arranged sequentially along a direction from the display area DA (see FIG. 5) toward the opening area OA. The first groove 1G may be disposed between the first partition wall PW1 and the first sub-intermediate area SMA1. In other words, the first groove 1G may be disposed between the first partition wall PW1 and the display area DA (see FIG. 5). The second groove 2G, the third groove 3G, and the fourth groove 4G may be disposed between the first partition wall PW1 and the second partition wall PW2, and the fifth groove 5G and the sixth groove 6G may be disposed between the second partition wall PW2 and the opening area OA. Specifically, the second groove 2G may be disposed between the first partition wall PW1 and the first sub-partition wall SW1, the third groove 3G may be disposed between the first sub-partition wall SW1 and the second sub-partition wall SW2, and the fourth groove 4G may be disposed between the second sub-partition wall SW2 and the second partition wall PW2. The fifth groove 5G may be disposed between the second partition wall PW2 and the dam CD, and the sixth groove 6G may be disposed between the dam CD and the opening area OA.

In an embodiment, the first partition wall PW1 may include first to fourth partition wall layers 1110, 1120, 1130, and 1140, respectively. The partition wall layers 1110, 1120, 1130, and 1140 may include the same materials as those of the first organic insulating layer 211, the second organic insulating layer 213, the bank layer 215 (see FIG. 6), and the spacer 217 (see FIG. 6), respectively. A first protrusion 1141 and a second protrusion 1142 may be formed on the fourth partition wall layer 1140, and the first protrusion 1141 and the second protrusion 1142 may include the same material as the spacer 217 (see FIG. 6). The second partition wall PW2 may, similarly to the first partition wall PW1, include first to fourth partition wall layers 1210, 1220, 1230, 1240, respectively. The partition wall layers 1210, 1220, 1230, and 1240 may include the same materials as those of the first organic insulating layer 211, the second organic insulating layer 213, the bank layer 215, and the spacer 217, respectively.

In an embodiment, the first sub-partition wall SW1 may include a first partition wall layer 1310 and a second partition wall layer 1320, and the second sub-partition wall SW2 may include a first partition wall layer 1410 and a second partition wall layer 1420. Similarly, the dam CD may include a first partition wall layer 1510 and a second partition wall layer 1520. The first partition wall layer 1310 of the first sub-partition wall SW1, the first partition wall layer 1410 of the second sub-partition wall SW2, and the first partition wall layer 1510 of the dam CD may include the same material as the first organic insulating layer 211. The second partition wall layer 1320 of the first sub-partition wall SW1, the second partition wall layer 1420 of the second sub-partition wall SW2, and the second partition wall layer 1520 of the dam CD may include the same material as the second organic insulating layer 213.

In an embodiment, at least one of the grooves G may include a tip PT. In an embodiment, as illustrated in FIG. 7, each of the grooves 1G, 2G, 3G, 4G, 5G, and 6G may include at least one tip PT. For example, the first groove 1G may have tips PT on both sides of a virtual vertical line VXL passing through the center of the first groove 1G. Like the first groove 1G, the second groove 2G may also include a pair of tips PT. In contrast, the third groove 3G, the fourth groove 4G, and the sixth groove 6G may include one tip PT as shown in FIG. 7. In an embodiment, the fifth groove 5G may include tips PT and PT1 positioned on both sides of the fifth groove 5G.

In other words, in an embodiment, the tip PT may be disposed on the side of the partition walls. For example, the first partition wall PW1 may include the tip PT disposed on a side facing the first groove 1G and protruding toward the first groove 1G. For example, the first partition wall PW1 may include the tip PT disposed on a side facing the second groove 2G and protruding toward the second groove 2G. The first sub-partition wall SW1 may include the tip PT protruding toward the second groove 2G on one side, and the second sub-partition wall SW2 may include the tip PT protruding toward the third groove 3G on one side. The second partition wall PW2 may include the tip PT protruding toward the fourth groove 4G on one side and the tip PT protruding toward the fifth groove 5G on the other side. The dam CD may include a first tip PT1 protruding toward the fifth groove 5G on one side and a second tip PT2 protruding toward the sixth groove 6G on the other side.

In an embodiment, the tip PT may be provided with a metal pattern layer 212, where the metal pattern layer 212 may include a first metal pattern layer 1212 disposed directly on the third interlayer insulating layer 210 and a second metal pattern layer 2212 disposed directly on the first organic insulating layer 211. The first metal pattern layer 1212 is arranged on substantially the same layer as the node connection line 166 described with reference to FIG. 6, and may include the same material as the node connection line 166. In another embodiment, the first metal pattern layer 1212 may include the same material as a third metal layer 113 of a metal dummy stack 110 to be described later. For example, the first metal pattern layers 1212 may have a three-layer structure of Ti/Al/Ti. The second metal pattern layer 2212 may include the same metal as the data line DL and/or the driving voltage line PL described above with reference to FIG. 6. According to an embodiment, the second metal pattern layer 2212 may have a three-layer structure of Ti/Al/Ti.

In an embodiment, the metal pattern layer 212 may be disposed on at least one side of the groove G. For example, the second metal pattern layer 2212 may be disposed on both sides of a virtual vertical line VXL passing through the center of the first groove 1G, and ends of each second metal pattern layer 2212 may protrude toward the center of the first groove 1G to define the tip PT. The tip PT is a type of caves portion and may pass through the inner surface of the first organic insulating layer 211 forming the inner surface of the first groove 1G and protrude the center of the first groove 1G.

Similarly, in an embodiment, the second metal pattern layers 2212 may be disposed on both sides of the second groove 2G, and ends of each of the second metal pattern layers 2212 may protrude toward the center of the second groove 2G to define the tip PT. The first partition wall PW1 may include the tip PT protruding toward the second groove 2G disposed on one side, and the first sub-partition wall SW1 may include the tip PT protruding toward the second groove 2G disposed on one side.

In an embodiment, the third groove 3G may include one tip PT, where the tip PT may be positioned on one side of the third groove 3G, for example, one side adjacent to a second sub-partition wall SW2. The second metal pattern layer 2212 is positioned on one side of the third groove 3G, and an end of the second metal pattern layer 2212 may protrude past the first organic insulation layer 211 forming the inner surface of the third groove 3G toward the center of the third groove 3G to form the tip PT. That is, one side of the second sub-partition wall SW2 may include the tip PT protruding toward the third groove 3G.

In an embodiment, the fourth groove 4G may include one tip PT, where the tip PT may be positioned on one side of the fourth groove 4G, for example, one side adjacent to a second partition wall PW2. The second metal pattern layer 2212 is positioned on one side of the fourth groove 4G, and an end of the second metal pattern layer 2212 may protrude past the first organic insulation layer 211 forming the inner surface of the fourth groove 4G toward the center of the fourth groove 4G to form the tip PT. That is, one side of the second partition wall PW2 may include the tip PT protruding toward the fourth groove 4G.

In an embodiment, the fifth groove 5G may include the tip PT provided with the second metal pattern layer 2212 disposed on one side and the first tip PT1 provided with the first metal pattern layer 1212 disposed on the other side. Specifically, an end of the second metal pattern layer 2212 disposed on the second partition wall PW2 may protrude toward the center of the fifth groove 5G to form the tip PT. The second metal pattern layer 2212 is positioned on one side of the fifth groove 5G, and an end of the second metal pattern layer 2212 may protrude past the first organic insulation layer 211 forming the inner surface of the fifth groove 5G toward the center of the fifth groove 5G to form the tip PT. That is, one side of the second partition wall PW2 may include the tip PT protruding toward the fifth groove 5G.

Likewise, in an embodiment, an end of the first metal pattern layer 1212 disposed on the dam CD may protrude toward the center of the fifth groove 5G to form the first tip PT1. The first metal pattern layer 1212 is positioned on the other side of the fifth groove 5G, and an end of the first metal pattern layer 1212 may protrude past the third interlayer insulation layer 210 forming the inner surface of the fifth groove 5G toward the center of the fifth groove 5G to form the first tip PT1. That is, one side of the dam CD may include the first tip PT1 protruding toward the fifth groove 5G.

In an embodiment, the sixth groove 6G may include the second tip PT2 provided with a second metal pattern layer 2212. Specifically, an end of the second metal pattern layer 2212 disposed on the dam CD may protrude toward the center of the sixth groove 6G to form the second tip PT2. The second metal pattern layer 2212 is positioned on one side of the sixth groove 6G, and an end of the second metal pattern layer 2212 may protrude past the first organic insulation layer 211 forming the inner surface of the sixth groove 6G toward the center of the sixth groove 6G to form the second tip PT2. That is, the other side of the dam CD may include the second tip PT2 protruding toward the opening area OA.

In other words, in an embodiment, the dam CD may include the first tip PT1 provided with the first metal pattern layer 1212 and the second tip PT2 provided with a second metal pattern layer 2212. The first organic insulating layer 211 may be interposed between the first metal pattern layer 1212 and the second metal pattern layer 2212. That is, the first tip PT1 and the second tip PT2 may be disposed on different layers. The end of the first metal pattern layer 1212 may protrude toward the fifth groove 5G, and the end of the second metal pattern layer 2212 may protrude toward the sixth groove 6G. That is, the first tip PT1 may be arranged on one side facing the display area DA (see FIG. 5) among both sides of the dam CD, and the second tip PT2 may be arranged on the other side facing the opening area OA among both sides of the dam CD. The first tip PT1 and the second tip PT2 are respectively disposed on both sides of the dam CD, but are disposed on different layers, so that the dam CD including the first tip PT1 and the second tip PT2 may have an asymmetric tip structure in the cross-section along the thickness direction of the substrate 100.

In an embodiment, some of the layers included in the organic light-emitting diode OLED, such as the first functional layer 222a and second functional layer 222c which are organic, may be disconnected by the grooves G including tips PT, PT1, and PT2. The second electrode 223 may also be disconnected or separated by the grooves G including tips PT, PT1, and PT2.

In this regard, FIG. 7 illustrates an embodiment where the first functional layer 222a, second functional layers 222c and the second electrode 223 are disconnected and separated by the tips PT, PT1, and PT2 of the grooves 1G, 2G, 3G, 4G, 5G, and 6G. Moisture and oxygen may penetrate into the display area DA (see FIG. 5) through the side surface of the opening 10OP of the display panel 10, and continuously formed organic layers, for example, the functional layers 222a and 222c may serve as the above-described moisture penetration path. However, as illustrated in FIG. 7, because the functional layers 222a and 222c are disconnected by the groove G including the tips PT, PT1, and PT2, moisture may be prevented from moving toward the display area DA (see FIG. 5).

In particular, the display panel 10, according to an embodiment, may more effectively prevent moisture and oxygen penetration from the outside since the dam CD includes the first tip PT1 and the second tip PT2. For example, if the dam CD includes only the second tip PT2, excessive stress may be concentrated in a specific area of the dam CD due to the tip formed only on one side, which may cause cracks or defects due to moisture penetration. In contrast, as shown in FIG. 7, when the dam CD forms the asymmetric tip structure including the first tip PT1 and the second tip PT2, the stress applied to the layers formed on the upper part of the dam CD is distributed, thereby preventing the phenomenon of excessive stress being concentrated in a specific area. That is, as the dam CD forms the asymmetric tip structure, defects such as cracks due to stress can be prevented, and the functional layers 222a and 222c and the second electrode 223 can be disconnected once more by the first tip PT1. In conclusion, the display panel, according to an embodiment, can effectively prevent moisture and oxygen penetration from the outside, thereby improving reliability.

In an embodiment, the metal dummy stack 110 may be around the groove G. For example, metal dummy stacks 110 may be disposed on both sides of the groove G. The metal dummy stack 110 is a type of mound and may increase the depth of the groove G. According to an embodiment, FIG. 7 illustrates that the metal dummy stack 110 includes three metal layers, for example, first to third metal layers 111, 112, and 113, respectively, overlapped each other with an insulating layer disposed therebetween.

In an embodiment, the metal layers 111, 112, and 113 may be disposed on the same layer and may include the same material as the electrodes of the transistors and the storage capacitor described above with reference to FIG. 6. For example, the first metal layer 111 may be disposed on the same layer and include the same material as the upper electrode CE2 (see FIG. 6) of the storage capacitor and/or the lower gate electrode G3A (see FIG. 6), which is the sub-layer of the third gate electrode GE3. The second metal layer 112 may be disposed on the same layer and may include the same material as the upper gate electrode G3B (see FIG. 6), which is the sub-layer of the third gate electrode GE3 (see FIG. 6). The third metal layer 113 may be disposed on the same layer and may include the same material as the node connection line 166 (see FIG. 6). Although FIG. 7 illustrates that the metal dummy stack 110 includes the three metal layers overlapping each other with the insulating layer disposed therebetween, the invention is not limited thereto. According to another embodiment, the number of metal layers of the metal dummy stack 110 may be less than or greater than three.

In an embodiment, an opening portion COP formed by etching a portion of at least one inorganic insulating layer among the plurality of inorganic insulating layers may be disposed under the dam CD. In this regard, FIG. 7 illustrates that the opening portion COP is formed by etching a portion of the buffer layer 201, the first gate insulating layer 203, the first interlayer insulating layer 205, the second interlayer insulating layer 207, the second gate insulating layer 209, and the third interlayer insulating layer 210 among the plurality of inorganic insulating layers, but is not limited thereto. In this case, the first metal pattern layer 1212 may extend to cover the opening portion COP. In other words, at least one inorganic insulating layer may be disconnected or separated by the first metal pattern layer 1212, where the first metal pattern layer 1212 is disposed on the same layer as one of the plurality of metal layers included in the metal dummy stack 110, and which may include the same material as that metal layer. FIG. 7 illustrates that the first metal pattern layer 1212 is disposed on the same layer as the third metal layer 113 and includes the same material as the third metal layer, but the invention is not limited thereto. Some area of the lower surface of the first metal pattern layer 1212 may be in contact with the lower metal layer 202. The lower metal layer 202 may be a metal layer positioned between the substrate 100 and the buffer layer 201.

In an embodiment, the opening portion COP separates the inorganic insulating layers that are disposed on the side of the first sub-intermediate area SMA1 and the inorganic insulating layers disposed on the side of the opening area OA to prevent cracks generated in the inorganic insulating layers disposed on the side of the opening area OA from propagating to the inorganic insulating layers disposed on the side of the first sub-intermediate area SMA1 when forming the opening 10OP of the display panel 10. In this case, the first metal pattern layer 1212 covers the opening portion COP of the plurality of inorganic insulating layers, thereby blocking a moisture-permeable path through which moisture or the like is transferred from the first organic insulating layer 211 to the substrate 100 through the opening portion COP.

Also, in an embodiment and as described above, the third groove 3G and the fourth groove 4G may include the tip PT disposed only on one side. In other embodiments, some of the grooves G, for example, the third groove 3G or the fourth groove 4G, may not include the tip PT. The third groove 3G or the fourth groove 4G may be used to monitor the organic encapsulation layer 320 of the encapsulation layer 300.

In an embodiment, the organic encapsulation layer 320 may be formed by applying and curing a monomer. Because the monomer has fluidity, controlling the position of the monomer is one of the important factors in manufacturing the display panel 10. The position of the organic encapsulation layer 320 may be measured by using the amount of light reflected after being irradiated onto the display panel. Because the tip PT including a metal affects the reflectance of light used to monitor the organic encapsulation layer 320, it may be difficult to track the position of the organic encapsulation layer 320 when all the grooves G include the tip PT. However, the display panel, according to some embodiments, may prevent or minimize the above-described situation by including the groove G in which the tip PT is formed on only one side or the groove G that does not have the tip PT.

In an embodiment, the grooves G disposed between the first partition wall PW and the second partition wall PW2 may be covered with the organic encapsulation layer 320. In this regard, FIG. 7 illustrates that the second groove 2G, the third groove 3G, and the fourth groove 4G are covered with the organic encapsulation layer 320 in an area between the first partition wall PW1 and the second partition wall PW2. If the groove G between the first partition wall PW1 and the second partition wall PW2 is not covered by the organic encapsulation layer 320, contact of inorganic insulating layers such as the first inorganic encapsulation layer 310 and the second inorganic encapsulation layer 330 may occur on the second groove 2G, the third groove 3G, and the fourth groove 4G. When the area of the contact region between the first inorganic encapsulation layer 310 and the second inorganic encapsulation layer 330 is relatively large on the second groove 2G, the third groove 3G, and the fourth groove 4G, cracks are likely to occur in the contact region between the first and second inorganic encapsulation layers 310 and 330, respectively, due to the uneven structure of the second groove 2G, the third groove 3G, and the fourth groove 4G itself. The cracks may deteriorate the quality of the display panel 10. However, according to an embodiment, because the organic encapsulation layer 320 covers the grooves G between the first partition wall PW1 and the second partition wall PW2, for example, the second groove 2G, the third groove 3G, and the fourth groove 4G, the above-described situation may be prevented or minimized.

In an embodiment, the first inorganic encapsulation layer 310 of the encapsulation layer 300 may continuously cover the inner surfaces of the grooves G, and the organic encapsulation layer 320 may cover the first sub-intermediate area SMA1 and may cover a portion of the second sub-intermediate area SMA2. The organic encapsulation layer 320 may cover some grooves G, for example, the first groove 1G and the grooves 2G, 3G and 4G located between the first partition wall PW1 and second partition wall PW2. The second inorganic encapsulation layer 330 may completely cover the intermediate area MA on the organic encapsulation layer 320.

In an embodiment, the first partition wall PW1 may include a plurality of protrusions so as to control the flow of the monomer when the organic encapsulation layer 320 is formed. According to an embodiment, FIG. 7 illustrates that the first partition wall PW1 includes the first protrusion 1141 and the second protrusion 1142 are spaced apart from each other.

In an embodiment, the organic encapsulation layer 320 may be discontinuous in the intermediate area MA due to the structure of the first partition wall PW1 or the like. For example, as illustrated in FIGS. 6 and 7, a portion of the organic encapsulation layer 320 may cover the display area DA and the first sub-intermediate area SMA1, and another portion thereof may cover an area located between the first partition wall PW1 and the second partition wall PW2. A portion of the second inorganic encapsulation layer 330 disposed on the second protrusion 1142 of the first partition wall PW1, which is a discontinuous point of the organic encapsulation layer 320, may be in direct contact with a portion of the first inorganic encapsulation layer 310.

In an embodiment, the end of the organic encapsulation layer 320 may be positioned on one side of the second partition wall PW2 and may not extend toward the opening area OA through the second partition wall PW2. Therefore, a portion of the second inorganic encapsulation layer 330 may be in direct contact with a portion of the first inorganic encapsulation layer 310 disposed on the upper surface of the second partition wall PW2. The second inorganic encapsulation layer 330 may be in direct contact with the first inorganic encapsulation layer 310 disposed between the second partition wall PW2 and the opening area OA.

In an embodiment, the touch insulating layers described above with reference to FIG. 6 may extend to the intermediate area MA. In this regard, FIG. 7 illustrates a structure in which the touch insulating layers 401, 403, and 405 extend to the intermediate area MA.

In an embodiment, the planarization layer 450 may be positioned in the intermediate area MA, where the planarization layer 450 may planarize the intermediate area MA. The planarization layer 450 may cover a structure that is positioned in the intermediate area MA, but that is provided under the planarization layer 450.

In an embodiment and referring to FIGS. 6 and 7, the planarization layer 450 may be positioned only in the intermediate area MA and may not exist in the display area DA (see FIG. 6). In this regard, FIG. 6 illustrates that an outer edge 450e of the planarization layer 450 is not positioned in the display area DA. The process of forming the planarization layer 450 may be performed between the process of forming the first touch insulating layer 401 and the process of forming the second touch insulating layer 403. Therefore, the first touch insulating layer 401 and the second touch insulating layer 403 may be in direct contact with each other in the display area DA located adjacent to the outer edge 450e of the planarization layer 450.

In an embodiment and referring to the opening area OA of FIG. 7, the display panel 10 includes an opening 10OP, where the opening 10OP of the display panel 10 may include openings of elements constituting the display panel 10. For example, the opening 10OP of the display panel 10 may include an opening of the substrate 100, openings of the inorganic encapsulation layers 310 and 330 of the encapsulation layer 300, and an opening of the planarization layer 450. The openings of the elements constituting the display panel 10 may be formed at the same time. Accordingly, the inner surface of the substrate 100 defining the opening of the substrate 100 and the inner surface of the planarization layer 450 defining the opening of the planarization layer 450 may be located on the same vertical line.

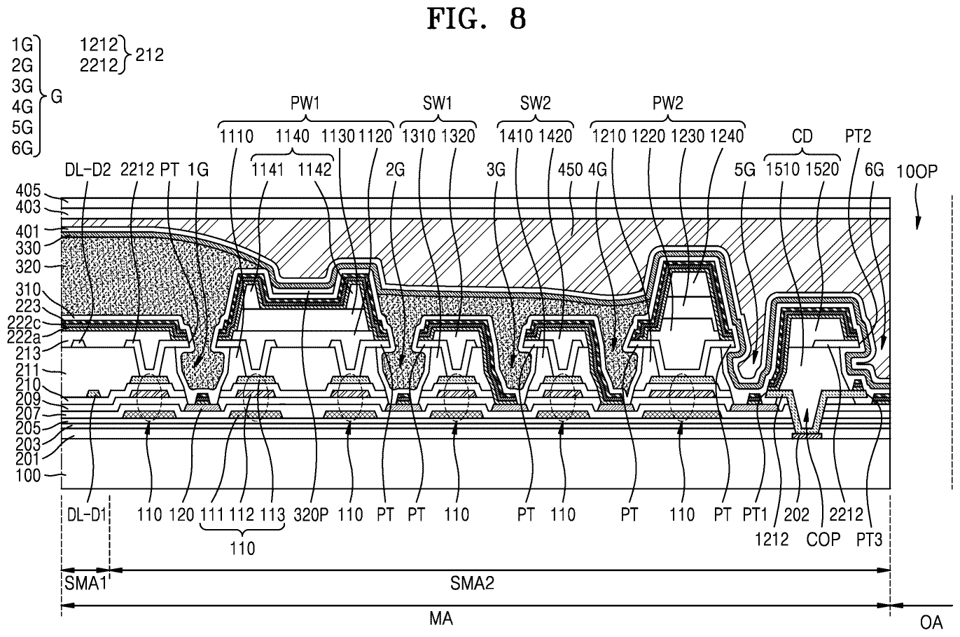

FIG. 8 is a cross-sectional view of a display panel 10, according to another embodiment. Referring to FIG. 8, except for the features of the dam CD, other features are the same as those described in FIGS. 5 to 7. The same reference numerals among the elements of FIG. 8 are the same as described above with reference to FIGS. 5 to 7, and hereinafter, differences will be mainly described.

In an embodiment and referring to the second sub-intermediate area SMA2 of FIG. 8, the grooves G may be spaced apart from each other. In this regard, FIG. 7 illustrates that grooves 1G, 2G, 3G, 4G, 5G, and 6G are arranged in a direction from the first sub-intermediate area SMA1 to the opening area OA. The grooves 1G, 2G, 3G, 4G, 5G, and 6G may have a closed loop shape surrounding the opening area OA in a plan view as described above with reference to FIG. 5.

In an embodiment, since the grooves G are formed by penetrating at least one insulating layer, partition walls in addition to the grooves G may be located in the intermediate area MA. In this regard, FIG. 8 illustrates a first partition wall PW1, a second partition wall PW2, a first sub-partition wall SW1, a second sub-partition wall SW2, and a dam CD. The grooves G, including grooves 1G to 6G, may be spaced apart from each other in the second sub-intermediate area SMA2. The first partition wall PW1, the second partition wall PW2, the first sub-partition wall SW1, the second sub-partition wall SW2, and the dam CD may have a closed loop shape in a plan view, similar to the grooves G.

In an embodiment, at least one of the grooves G may include a tip PT. In an embodiment, as illustrated in FIG. 8, each of the grooves 1G, 2G, 3G, 4G, 5G, and 6G may include at least one tip/PT.

For example, in an embodiment, the fifth groove 5G may include the tip PT provided with the second metal pattern layer 2212 disposed on one side and the first tip PT1 provided with the first metal pattern layer 1212 disposed on the other side. Specifically, an end of the second metal pattern layer 2212 disposed on the second partition wall PW2 may protrude toward the center of the fifth groove 5G to form the tip PT. The second metal pattern layer 2212 is positioned on one side of the fifth groove 5G, and an end of the second metal pattern layer 2212 may protrude past the first organic insulation layer 211 forming the inner surface of the fifth groove 5G toward the center of the fifth groove 5G to form the tip PT. That is, one side of the second partition wall PW2 may include the tip PT protruding toward the fifth groove 5G.

Likewise, in an embodiment, an end of the first metal pattern layer 1212 disposed on the dam CD may protrude toward the center of the fifth groove 5G to form the first tip PT1. The first metal pattern layer 1212 is positioned on the other side of the fifth groove 5G, and an end of the first metal pattern layer 1212 may protrude past the third interlayer insulation layer 210 forming the inner surface of the fifth groove 5G toward the center of the fifth groove 5G to form the first tip PT1. That is, one side of the dam CD may include the first tip PT1 protruding toward the fifth groove 5G.

In an embodiment, the sixth groove 6G may include the second tip PT2 provided with the second metal pattern layer 2212 and the third tip PT3 provided with the first metal pattern layer 1212. Specifically, an end of the second metal pattern layer 2212 disposed on the dam CD may protrude toward the center of the sixth groove 6G to form the second tip PT2. The second metal pattern layer 2212 is positioned on one side of the sixth groove 6G, and an end of the second metal pattern layer 2212 may protrude past the first organic insulation layer 211 forming the inner surface of the sixth groove 6G toward the opening area OA to form the second tip PT2.

In addition, in an embodiment, the end of the first metal pattern layer 1212 disposed on the dam CD may protrude toward the center of the sixth groove 6G to form the third tip PT3. The first metal pattern layer 1212 may extend from one side surface of the dam CD disposed adjacent to the fifth groove 5G to the other side surface of the dam CD disposed adjacent to the sixth groove 6G. The end of the first metal pattern layer 1212 extending to the side surface disposed adjacent to the sixth groove 6G may protrude toward the opening area OA by passing through the third interlayer insulating layer 210 forming an inner surface of the sixth groove 6G to form the third tip PT3. That is, the other side of the dam CD may include the second tip PT2 and the third tip PT3 protruding toward the sixth groove 6G.

In other words, in an embodiment, the dam CD may include the first tip PT1 and the third tip PT3 provided with the first metal pattern layer 1212 and the second tip PT2 provided with the second metal pattern layer 2212. The first organic insulating layer 211 may be interposed between the first metal pattern layer 1212 and the second metal pattern layer 2212. That is, the first tip PT1 and the third tip PT3 may be formed by extending the first metal pattern layer 1212 on both sides of the dam CD, but the first tip PT1 and the second tip PT2 may be disposed on different layers, and the third tip PT3 and the second tip PT2 may be disposed on different layers. The end of the first metal pattern layer 1212 may protrude in both directions toward the fifth groove 5G and the sixth groove 6G, and the end of the second metal pattern layer 2212 may protrude toward the sixth groove 6G. That is, the first tip PT1 may be arranged on one side facing the display area DA (see FIG. 5) among both sides of the dam CD, and the second tip PT2 and the third tip PT3 may be arranged on the other side facing the opening area OA among both sides of the dam CD. Accordingly, the dam CD including the first tip PT1, the second tip PT2, and the third tip PT3 may have an asymmetric tip structure in a cross section along the thickness direction of the substrate 100.

Accordingly, the display panel, according to an embodiment, may more effectively prevent moisture and oxygen penetration from the outside since the dam CD includes the first tip PT1, the second tip PT2 and the third tip PT3. As described above, when the dam CD includes only the second tip PT2, excessive stress may be concentrated in a specific area of the dam CD, resulting in defects such as cracks. In contrast, as shown in FIG. 8, when the dam CD forms the asymmetric tip structure including the first tip PT1, the second tip PT2, and the third tip PT3, stress applied to the layers formed on the upper part of the dam CD is distributed, thereby preventing concentration of excessive stress in a specific area. That is, as the dam CD forms the asymmetric tip structure, defects such as cracks due to stress can be prevented, and the functional layers 222a and 222c and the second electrode 223 may be disconnected twice more by the first tip PT1 and the third tip PT3. In conclusion, the display panel, according to another embodiment, may effectively prevent moisture and oxygen penetration from the outside, thereby improving reliability.

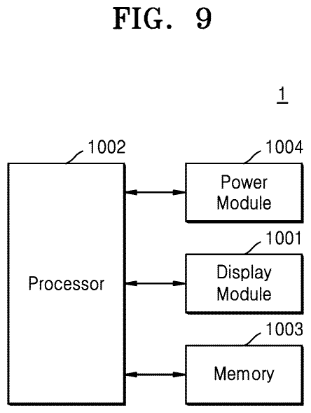

The display panel according to the embodiment may be applied to various electronic apparatuses. An electronic apparatus according to an embodiment of the present disclosure may include the display panel (e.g., the display panel of FIG. 3) described above, and may further include modules or appratuses having additional functions in addition to the display panel. FIG. 9 is a block diagram of an electronic apparatus according to an embodiment.

Referring to FIG. 9, an electronic apparatus 1 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic apparatus 1.

At least one of the components of the electronic apparatus 1 described above may be included in the display panel according to the embodiments described above. In addition, a part among the individual modules functionally included in one module may be included in the display panel, and another part may be provided separately from the display panel. For example, the display panel may include the display module 1001, and the processor 1002, the memory 1003, and the power module 1004 may be provided in the form of other apparatuses within the electronic apparatus 1 except for the display panel.

In an embodiment, the display module 1001 included in the display panel may drive based on the image data signal and the input control signal received from the processor 1002.

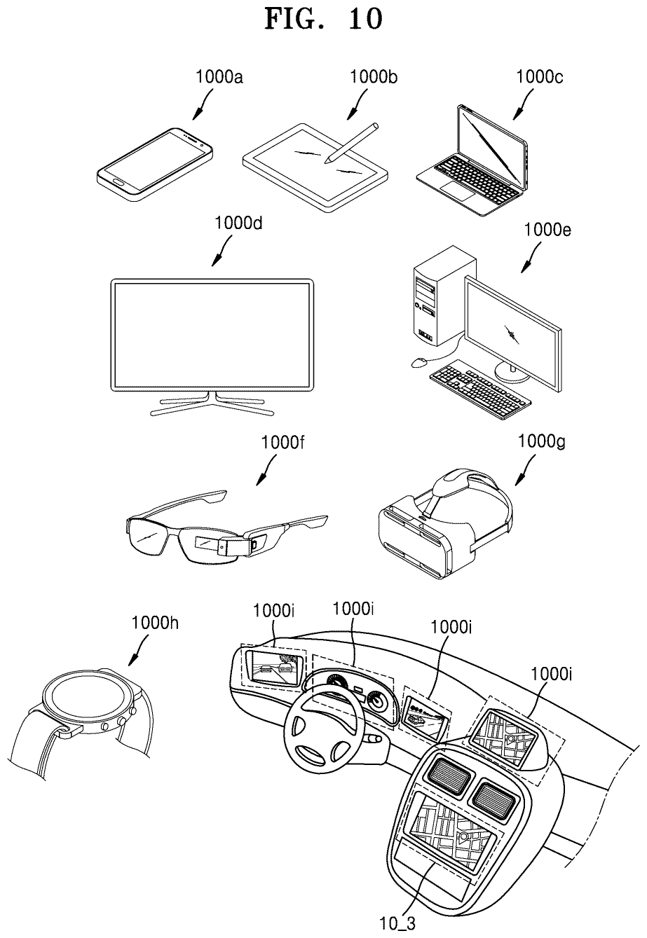

FIG. 10 is schematic diagrams of electronic apparatuses according to various embodiments.

Referring to FIG. 10, various electronic apparatuses to which display panels according to embodiments are applied may include not only image display electronic apparatuses such as a smart phone 1000a, a tablet PC 1000b, a laptop 1000c, a TV 1000d, and a desk monitor 1000c, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

The display panel, according to some embodiments, may prevent external impurities such as moisture from damaging display elements around the opening area, and address situations such as cracks in the intermediate area around the opening area. However, this is merely an example, and the scope of the invention is not limited thereby.

Although the invention has been described with reference to embodiment(s) illustrated in the drawings, this is only exemplary, and those skilled in the art will understand that various modifications may be made therefrom.

It should be understood that the invention described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display panel comprising:
a substrate comprising an opening, a display area surrounding the opening, and an intermediate area disposed between the opening and the display area;
a plurality of light-emitting diodes disposed on the display area; and
a dam disposed on the intermediate area, wherein
a first side of the dam comprises a first tip protruding toward the display area,
a second side of the dam comprises a second tip protruding toward the opening, and
the first tip and the second tip are disposed on different layers.

2. The display panel of claim 1, wherein,
when viewed from a direction perpendicular to the substrate,
the dam has a closed loop shape surrounding the opening.

3. The display panel of claim 1, wherein,
in a cross section directed along a thickness direction of the substrate,
the first tip and the second tip of the dam are asymmetrical.

4. The display panel of claim 1, further comprising:
at least one inorganic insulating layer disposed on the substrate; and
a plurality of grooves disposed in the intermediate area of the substrate and in the at least one inorganic insulating layer.

5. The display panel of claim 4, wherein
the dam further comprises:
a first metal pattern layer disposed on the at least one inorganic insulating layer;
an organic insulating layer disposed on the first metal pattern layer; and
a second metal pattern layer disposed on the organic insulating layer, wherein
the first tip comprises the first metal pattern layer, and
the second tip comprises the second metal pattern layer.

6. The display panel of claim 5, wherein
the at least one inorganic insulating layer is bisected by the first metal pattern layer.

7. The display panel of claim 5, wherein
each of the plurality of light-emitting diodes is connected to a sub-pixel circuit disposed on the substrate, and
the sub-pixel circuit comprises a silicon transistor comprising a silicon-based semiconductor layer and an oxide transistor comprising an oxide-based semiconductor layer, and
the first metal pattern layer is disposed on a same layer as a node electrode connecting the silicon transistor to the oxide transistor, and
the second metal pattern layer is disposed on a same layer as a data line connected to the sub-pixel circuit.

8. The display panel of claim 7, wherein
a lower layer is disposed under each of the plurality of grooves, and
an upper surface of the lower layer corresponds to a bottom surface of each of the plurality of grooves, and
the lower layer includes a same material as the oxide-based semiconductor layer.

9. The display panel of claim 4, further comprising
a first partition wall and a second partition wall disposed on the intermediate area of the substrate,
wherein the first partition wall, the second partition wall, and the dam are arranged along a direction extending from the display area toward the opening.

10. The display panel of claim 9, wherein
at least one groove among the plurality of grooves is disposed between the second partition wall and the dam, and
the first tip protrudes toward the at least one groove disposed between the second partition wall and the dam.

11. The display panel of claim 9, further comprising
a first sub-partition wall and a second sub-partition wall disposed on the intermediate area of the substrate,
wherein the first sub-partition wall and the second sub-partition wall are disposed between the first partition wall and the second partition wall.

12. The display panel of claim 1, wherein
each of the plurality of the light-emitting diodes comprises:
an emission layer disposed between a first electrode and a second electrode; and
a functional layer disposed between the first electrode and the second electrode,
wherein each of the functional layer and the second electrode is disconnected or separated by at least one of the first tip and the second tip.

13. The display panel of claim 1, wherein
the second side of the dam further comprises a third tip protruding in a direction toward the opening, and
the first tip and the third tip are arranged on a same layer.

14. A display panel comprising:
a substrate comprising an opening, a display area surrounding the opening, and an intermediate area disposed between the opening and the display area;
at least one inorganic insulating layer disposed on the substrate;
a plurality of light-emitting diodes disposed on the display area; and
a dam disposed on the intermediate area, wherein
the dam comprises:
a first metal pattern layer disposed on the at least one inorganic insulating layer;
an organic insulating layer disposed on the first metal pattern layer; and
a second metal pattern layer disposed on the organic insulating layer, wherein
the first metal pattern layer comprises a first tip protruding toward the display area, and the second metal pattern layer comprises a second tip protruding toward the opening.

15. The display panel of claim 14, wherein,
in a cross section along a thickness direction of the substrate,
the first tip and the second tip of the dam are asymmetrical.

16. The display panel of claim 14, wherein
the at least one inorganic insulating layer is bisected by the first metal pattern layer.

17. The display panel of claim 14, further comprising
a plurality of grooves disposed in the intermediate area and in the at least one inorganic insulating layer; and
a first partition wall and a second partition wall disposed on the intermediate area,
wherein the first partition wall, the second partition wall, and the dam are arranged along a direction from the display area toward the opening, and
at least one groove among the plurality of grooves is disposed between the second partition wall and the dam, and
the first tip protrudes toward a groove disposed between the second partition wall and the dam.

18. The display panel of claim 14, wherein
each of the plurality of the light-emitting diodes comprises:
an emission layer disposed between a first electrode and a second electrode; and
a functional layer disposed between the first electrode and the second electrode, wherein
each of the functional layer and the second electrode is disconnected or separated by at least one of the first tip and the second tip.

19. The display panel of claim 14, wherein
the first metal pattern layer further comprises a third tip protruding toward the opening.

20. An electronic apparatus, comprising:
a display panel, wherein the display panel includes,
a substrate comprising an opening, a display area surrounding the opening, and
an intermediate area disposed between the opening and the display area;
at least one inorganic insulating layer disposed on the substrate;
a plurality of light-emitting diodes disposed on the display area; and
a dam disposed on the intermediate area, wherein
the dam comprises:
a first metal pattern layer disposed on the at least one inorganic insulating layer;
an organic insulating layer disposed on the first metal pattern layer; and
a second metal pattern layer disposed on the organic insulating layer, wherein
the first metal pattern layer comprises a first tip protruding toward the display area, and the second metal pattern layer comprises a second tip protruding toward the opening.
